(19) United States
(12) Patent Application Publication
(10) Pub. No.: US 2024/0073306 A1
(43) Pub. Date: Feb. 29, 2024

(54) SELF TRANSFORMING WEARABLE SMARTPHONE

(71) Applicant: NIRMAN ENTERPRISES LTD, Haifa (IL)

(72) Inventor: Alan NIRMAN, Haifa (IL)

(21) Appl. No.: 18/271,477

(22) PCT Filed: Nov. 30, 2022
(86) PCT No.: PCT/IL2022/051277

§ 371 Date: Jul. 10, 2023

Related U.S. Application Data
(60) Provisional application No. 63/287,547, filed on Dec. 9, 2021.

(51) Int. Cl. H04M 1/02; H04B 1/3827

(52) U.S. Cl. CPC H04M 1/0268; H04B 1/385; H04M 1/0214

(57) ABSTRACT

Some embodiments of the current invention attempt to solve some or all above mentioned problems and/or tasks. An aspect of some embodiments of the invention, relates to a wearable smartphone e.g., that may be worn on one's wrist. According to some embodiments, the smartphone may be transformable between two or more configurations, e.g., from a flat smartphone form to a wearable form and/or vice versa. Optionally, a first configuration may be a flat form, and a second configuration may be a curved form. Optionally, the smartphone wearable form may be curved. Optionally, transformation between the two or more configurations may be reversible. In some embodiments, transformation is automatic, e.g., by pushing a button.

### RELATED APPLICATION/S

This application claims the benefit of priority under 35 USC § 119(e) of U.S. Provisional Patent Application No. 63/287,547 filed 9 Dec. 2021, the contents of which are incorporated herein by reference in their entirety.

### FIELD AND BACKGROUND OF THE INVENTION

The present invention, in some embodiments thereof, relates to a self transforming wearable smartphone.

Smartphones have become an integral part of modern life. For example, people store a lot of information on their smartphones and/or use it multiple times a day, e.g., as a clock, telephone, calendar, to store information, such as contact information, notes, etc., various forms of social communication, access to the internet, navigation, entertainment, etc.

Many people take their smartphone with them to most places they go. There are many situations where it is not convenient and/or not comfortable for people to carry the device in their hands or in their pocket or their bag e.g., during sports activities, while driving, in formal clothing, when needing two hands for a task such as picking up packages or small children, infirmity, injury, etc. Additionally, dropping a smartphone is a common occurrence and can damage one or more components for the smartphone, e.g., the screen, etc., which may be expensive to replace and may even necessitate buying a new smartphone. There are situations in which answering a call, text or using certain applications may be done without needing to take the smartphone out of one's pocket and/or may not require the use of one's hands, e.g., due to safety and/or efficiency, etc. such as while driving or operating machinery, etc. Smart apparel, such as smart glasses, smart watches, etc. may free up a user's hands but still require connection to a smartphone. This means that they are limited in the distance from the smartphone for optimal functioning and generally do not include all the functionality of a smartphone. In addition, smartwatches have small screen size which may be difficult to read, and limit visual functionality. As such, the user is may still carry the smartphone with them or keep it in close proximity which may be uncomfortable or inconvenient in some circumstances.

### SUMMARY

According to an aspect of some embodiments of the invention, there is provided a wearable smartphone including: a flexible structure including a plurality of tiles; an integrated view screen across a surface including a surface of each of the plurality of tiles; a switch; and a bending apparatus configured to reversibly change the smartphone from a flat configuration to a curved configuration in response to activating the switch.

According to some embodiments of the invention, the view screen includes a flexible portion attached to multiple tiles of the plurality of tiles and bending with the flexible structure.

According to some embodiments of the invention, each tile of the plurality of tiles is connected to a next tile by at least one hinge.

According to some embodiments of the invention, the bending apparatus includes at least one string attached to at least one actuator, and wherein the actuator is configured to reversibly put tension on the at least one string, thereby transforming the smartphone from the flat configuration to the curved configuration.

According to some embodiments of the invention, the string is threaded through at least one connecting element connected to a least one of the plurality of tiles.

According to some embodiments of the invention, the smartphone is configured transform to an intermediate configuration between the flat configuration and the curved configuration.

According to some embodiments of the invention, the intermediate configuration is adjustable by a user.

According to some embodiments of the invention, the wearable smartphone is lockable in a selected configuration.

According to some embodiments of the invention, the wearable smartphone is lockable in a selected configuration.

According to some embodiments of the invention, the plurality of tiles overlap at least in part.

According to some embodiments of the invention, the wearable smartphone of further includes a flexible battery.

According to some embodiments of the invention, the wearable smartphone of further includes at least one inflexible battery attached to at least one tile of the plurality of tiles.

According to some embodiments of the invention, the wearable smartphone of further includes one or more components selected from the group consisting of a speaker, microphone, front camera, back camera, switch, batteries, processor, sensors, charger, antenna, Global Positioning System (GPS), magnetometer, proximity sensors, barometer, gyroscope, accelerometer, altimeter, thermometer, projector, Bluetooth, Wi-Fi, multimedia functionality, social media access and wireless communications protocols.

According to some embodiments of the invention, the switch includes a button.

According to some embodiments of the invention, the wearable smartphone of further includes a button to lock and unlock the smartphone in a desired configuration.

According to some embodiments of the invention, the button is graphical.

According to some embodiments of the invention, the button is graphical.

According to some embodiments of the invention, the button is physical.

According to some embodiments of the invention, the button is physical.

According to some embodiments of the invention, the smartphone is operable in the flat configuration, the curved configuration and any intermediate configuration therebetween.

According to some embodiments of the invention, in the curved configuration the smartphone is curved away from the screen.

According to an aspect of some embodiments of the invention, there is provided a method for transforming a wearable smartphone made from a plurality of tiles from a flat configuration to a curved configuration including: triggering a switch on the wearable smartphone; activating an actuator in response to the triggering; reversibly creating torsion between at least two of the plurality of tiles; and transforming the configuration of the smartphone as a result of the reversibly creating torsion.

According to some embodiments of the invention, the actuator is connected to a string and wherein the activating creates tension in the string which in turn produces the torsion.

According to some embodiments of the invention, the actuator is connected to a hinge between the at least two of the plurality of tiles and wherein the torsion is on the hinge.

According to some embodiments of the invention, the transforming is to any intermediate configuration between the flat configuration and the curved configuration.

According to some embodiments of the invention, the transforming is automatic.

According to some embodiments of the invention, the transforming is manual.

According to some embodiments of the invention, a degree of transforming is controlled by a user. According to some embodiments of the invention, the flat configuration, the curved configuration and at least one intermediate configuration are defined by a user.

According to some embodiments of the invention, the method further includes reversibly locking the smartphone in a desired configuration.

According to some embodiments of the invention, the method further includes reversibly locking the smartphone in a desired configuration.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the figures:

FIG. 1 is a flow chart illustrating a method in accordance with an embodiment of the current invention.

FIG. 2 is a flow chart illustrating a method in accordance with an embodiment of the current invention.

FIG. 3 is a flow chart illustrating device in accordance with an embodiment of the current invention.

FIG. 4 is a block diagram illustrating a system in accordance with an embodiment of the current invention.

FIG. 5 is a schematic illustration illustrating a device in accordance with an embodiment of the current invention.

FIG. 6 is a schematic diagram illustrating a device in accordance with an embodiment of the current invention.

FIG. 7 is a schematic diagram illustrating a device in accordance with an embodiment of the current invention.

FIGS. 8A-B are schematic diagrams illustrating various configurations of a device in accordance with an embodiment of the current invention.

FIG. 9 is a schematic expanded diagram illustrating a device in accordance with an embodiment of the current invention.

FIGS. 10A-D are schematic diagrams illustrating various configurations of a device in accordance with an embodiment of the current invention.

FIGS. 11A-B are schematic diagrams illustrating a mechanism of a device in accordance with an embodiment of the current invention.

FIGS. 12A-B are schematic diagrams illustrating a mechanism of a device in accordance with an embodiment of the current invention.

FIGS. 13A-E are schematic diagrams illustrating a mechanism of a self-transforming device in accordance with an embodiment of the current invention.

FIGS. 14A-F are schematic diagrams illustrating various configurations of a device in accordance with an embodiment of the current invention.

FIG. 15 is a block diagram illustrating a device in accordance with an embodiment of the current invention.

FIG. 16 is a flow diagram illustrating a method for using a device in accordance with an embodiment of the current invention.

### DESCRIPTION OF SPECIFIC EMBODIMENTS OF THE INVENTION

### Overview

Some embodiments of the current invention may solve some or all the goals listed above, under certain conditions.

The term “smartphone” as used herein, relates to a personal portable computer device that combines mobile telephone and additional computing functions into one unit. Optionally, the smartphone may include functionality such as access to the internet (including web browsing e.g., over a cellular network, satellite network, etc.), multimedia functionality (e.g., music, video, gaming, VR, etc.), social media access, support wireless communications protocols (such as Bluetooth, Wi-Fi, satellite navigation, etc.), alongside core phone functions such as voice and/or video calls and text messaging. Optionally, the smartphone may include one or more sensors, such as one or more cameras, magnetometer, proximity sensors, barometer, gyroscope, accelerometer, altimeter, thermometer, etc. Optionally, the smartphone may include one or more projectors, such as speakers, sound projectors, visual projectors, holographic projectors, etc.

More and more situations are arising in daily functioning where a smartphone is wanted or needed but is uncomfortable or inconvenient to carry. Therefore, there is a recognized need for a wearable smartphone which is comfortable, can be strongly attached to a user and/or is transformable to multiple forms depending on the situation requirements.

Some embodiments of the current invention attempt to solve some or all above mentioned problems and/or tasks. An aspect of some embodiments of the invention, relates to a wearable smartphone e.g., that may be worn on one's wrist. According to some embodiments, the smartphone may be transformable between two or more configurations, e.g., from a flat smartphone form to a wearable form and/or vice versa. Optionally, a first configuration may be a flat form, and a second configuration may be a curved form. Optionally, the smartphone wearable form may be curved. Optionally, transformation between the two or more configurations may be reversible.

According to some embodiments, the smartphone may be transformable to an intermediate configuration between the first configuration and the second configuration. Alternatively, and/or additionally, the smartphone may be transformable to a desired in-between state e.g., a slightly curved configuration, as opposed to being flat, e.g., in a first configuration and/or round, e.g., in a second configuration. Advantageously, this may be useful in allowing a user to hang their smartphone in places when needed and/or to stand it up on a table and/or dashboard and/or to remain noticeable and not be lost between papers and/or books, and/or in a bag.

According to some embodiments, the smartphone may be used in a flat configuration, e.g., like a standard smartphone, such as held in a users' hand, placed on a flat surface, in a dedicated holder, in a users' pocket or bag, etc. Alternatively, and/or additionally, the smartphone may be wearable. Optionally, the smartphone may be worn on an item of clothing e.g., in a curved configuration (such as curved about a strap of a bag, attached to a belt, lanyard, etc.). Optionally, the smartphone may be worn on a users' body e.g., in a curved configuration curved about a users' wrist, upper arm, ankle, etc. Optionally, the smartphone may be an accessory such as a watch, bracelet, etc. Alternatively, and/or additionally, the smartphone in wearable configuration may be adjusted according to the requirements of the user. Optionally, the smartphone configuration may be adjusted to fit a selected body part (e.g., wrist, upper arm, ankle, etc.). Optionally, the smartphone configuration may be adjusted for a desired fit e.g., tighter and/or looser.

Alternatively, and/or additionally, the intermediate configuration of the smartphone may be slightly curved and/or more curved to various degrees in order to be worn by a variety of users, e.g., around the wrist of a user who may be a small child and/or a large adult.

Alternatively, and/or additionally, the current product may be curved with the smartphone screen facing inwards (e.g., towards the wrist of the user) and/or outwards (e.g., away from the wrist of the user). For example, this may be useful to protect the smartphone screen. Optionally, the smartphone configuration may be adjusted for a particular display, to stand on a selected side and/or to reduce glare, e.g., to curve the screen for optimal viewing of the display, such as while watching video content and/or to provide a stable stand to for providing video content, such as a stand for a camera in a video conference and/or for recording social media content, etc.

According to some embodiments, the smartphone may be programmable to one or more preprogramed configurations, e.g., flat, curved, various intermediate curvatures, etc. Optionally, smartphone may be programmable the remember one or more user preferred intermediate configurations. Optionally, the first configuration, second configuration and one or more intermediate configurations may be defined by a user.

According to some embodiments, the smartphone may be operational to make and/or receive smartphone calls and/or use various applications in all or some of the smartphone's transformable configurations. Alternatively, and/or additionally, the smartphone may be operational to perform any or some of its tasks by means of a vocal command and/or a specific motion.

According to some embodiments, the smartphone may be transformed to and/or from some or all of its configurations by one or more switches, e.g., a push button and/or a knob. Alternatively, and/or additionally, this switch may be physical and/or graphical (for example on the smartphone screen). Optionally, transformation of the smartphone to and/or from its various configurations may be automatic and/or manual. In some embodiments this transformation may be performed with one hand, e.g., automatically at the push of a button and/or manually by applying pressure with fingers on two specific locations on the smartphone to change the configuration).

According to some embodiments, the smartphone may be locked (i.e., set in a state where transformation is not possible) and/or unlocked (i.e., set in a state where transformation is possible). Optionally, the smartphone may be locked and/or unlocked in some and/or all of its configurations by means of one or more switches. Alternatively, and/or additionally, this switch may be physical and/or graphical. Alternatively, and/or additionally, this locking and/or opening may be automatic (e.g., mechanically through a processor following a preset series of instructions) and/or manually performed (e.g., a user may flatten out the smartphone with their hands and/or roll it around their wrist). Optionally, locking the wearable smartphone in a selected configuration may prevent it from falling off a user, e.g., while performing a physical activity such as sport, carrying an object, etc. Alternatively, and/or additionally, the smartphone may be set to require a code to change configurations. Optionally, this may prevent the smartphone from being stolen out of a users' hands or from a particular location. For example, the smartphone may be able to be closed tightly in its circular form around a users' wrist or another object allowing a user to securely leave the smartphone somewhere, and prevent it being removed and/or stolen.

### SPECIFIC EMBODIMENTS

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Reference is now made to the figures.

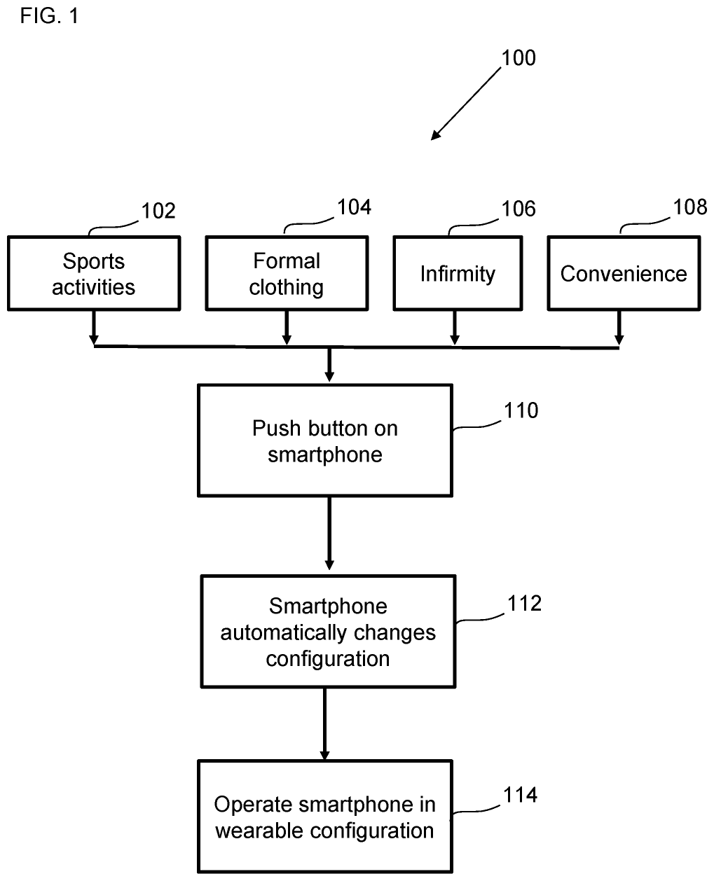

FIG. 1 is a flow chart illustrating a method in accordance with an embodiment of the current invention. For example, a process 100 showing various activities in which a wearable smartphone may be used. Such as, a user may be engaged in a sports activity 102, need to wear 104 formal clothing (e.g., without damaging the line or fit of the clothes or having to carry a large bag, etc.), may be infirm 106 (e.g., have shaky hands, injury, etc.), or may require the convenience 108 of having two hands free (e.g., carrying a package or small child, driving, operating machinery, cooking, etc.). The user may push 110 a button on the wearable smartphone which may causes it to reversibly open and/or close automatically, thereby changing 112 the smartphone's configuration, e.g., to wrap around a users' wrist. The user may then operate 114 the smartphone in a wearable configuration. Optionally, the smartphone may be operable in the first configuration, the second configuration and any intermediate configuration therebetween. Optionally, the user may lock the smartphone on their wrist possibly to avoid the smartphone from falling. Additionally or alternatively, the smartphone may have various decorative patterns on some or all its screen. For example, a user may choose and/or program a pattern and/or color for various parts of the phone when it is worn as a bracelet. For example, when the watch is worn as a bracelet, a collar and/or pattern of the exposed screen surface may be adjusted to match a user's clothing and/or for example, when wearing formal clothing the phone can adapt to have a formal watch faced and/or a leather strap and/or in a more informal setting the screen may display an image of an electronic screen and/or a surrounding portion may display a form of a colorful strap. Optionally, there may a be few predetermined and/or editable displays.

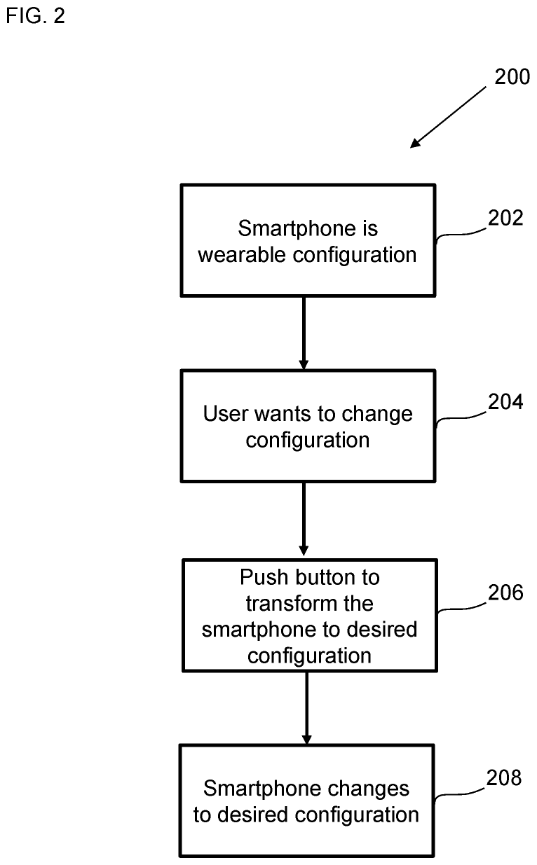

FIG. 2 is a flow chart illustrating a method in accordance with an embodiment of the current invention. For example, in a method 200, the smartphone may be in a wearable configuration 202, the user may wish 204 to change the smartphones configuration. The user may push 206 a button to transform 208 the smartphone to the desired configuration.

According to some embodiments, the wearable smartphone may include a button that when pushed causes the smartphone to automatically transform between one or more configurations. Optionally, the one or more configurations may include a first configuration e.g., flat, and a second configuration, e.g., round. Optionally, the smartphone may be transformable to one or more intermediate configurations between the first configuration and the second configuration e.g., a slightly curved configuration. Alternatively, and/or additionally, the wearable smartphone may allow the user to select which configuration they desire and/or the curvature of the wearable smartphone. For example, there may be a settings button that allows the user to select how much the smartphone wraps around 360 degrees. Optionally, the wearable smartphone may curve the screen towards and/or away from the user. Optionally, the user may control the degree of transformation between the first configuration and the second configuration. Optionally, the user can control the display for control of the smartphone and/or appearance of the phone as a piece of apparel.

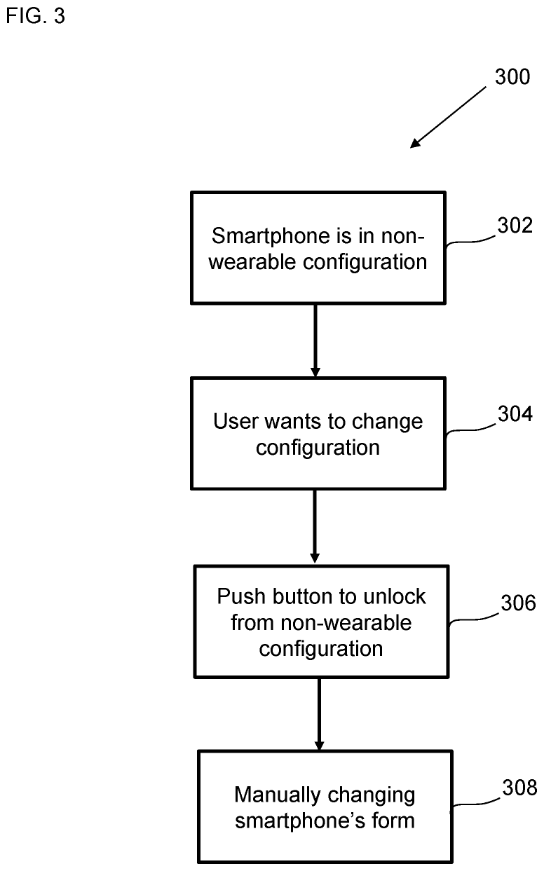

FIG. 3 is a flow chart illustrating device in accordance with an embodiment of the current invention. For example, in a method 300, the smartphone may be in a non-wearable configuration 302 (e.g., flat, etc.), the user may wish 304 to change the smartphones configuration. The user may push 306 a button to unlock the smartphone from its current configuration, allowing it to transform 308 to the desired configuration, manually or automatically.

According to some embodiments, the wearable smartphone may include a lock that holds the smartphone in its current configuration. When locked the smartphone may remain firmly in its current configuration. When unlocked the user may change the configuration of the smartphone. Alternatively, and/or additionally, changing the smartphones configuration may reversible. The wearable smartphone may include a button for locking the configuration, which may be physical and/or graphical.

According to some embodiments, transformation of the smartphone configuration be done manually and/or automatically. Alternatively, and/or additionally, the smartphone may have multiple press points that may allow the user to change the smartphone to and/or from various configurations with the use of one hand and/or one or more fingers.

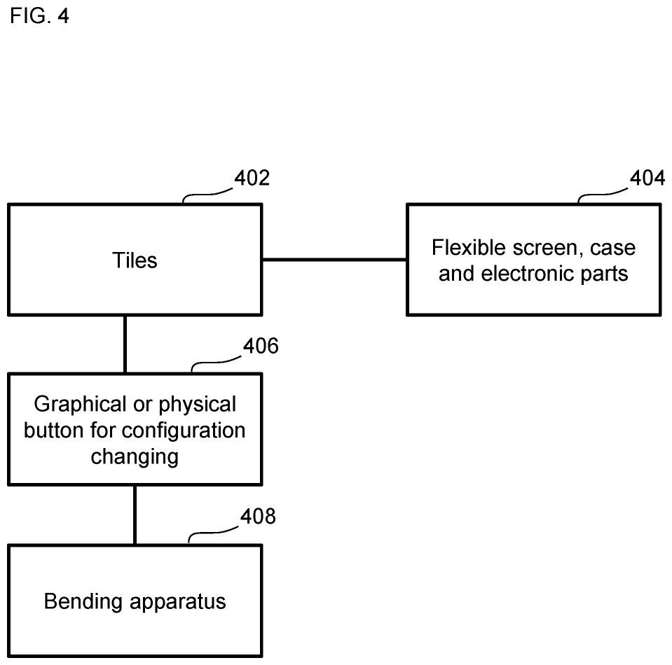

FIG. 4 is a block diagram illustrating a system in accordance with an embodiment of the current invention. For example, a wearable smartphone may be made of multiple tiles 402. Optionally, the smartphone may include one or more flexible components 404, such as a flexible screen, case, battery, electronic parts, etc. A flexible component may be connected to multiple tiles 402. Optionally the smartphone includes a bending apparatus 408 to manually and/or automatically change the configuration of the wearable smartphone. The wearable smartphone may include a button 406 for triggering configuration changing, which may be physical and/or graphical.

In some embodiments, triggering the button 406 activates the bending apparatus 408 to create torsion between the tiles 402 and/or bend a flexible element 404 thereby switching the configuration of the smartphone.

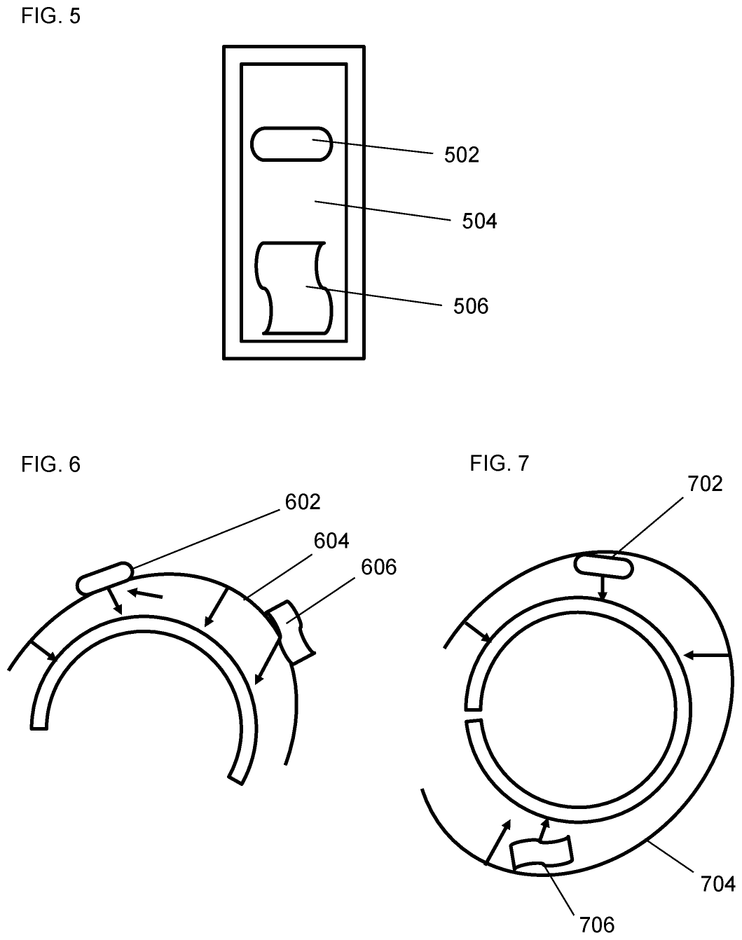

FIGS. 5, 6 and 7 are schematic illustrations illustrating a device in various configurations in accordance with some embodiments of the current invention. For example, the wearable smartphone may be transformable from a first configuration e.g., flat configuration (e.g., FIG. 5), through one or more intermediate configurations between the first configuration and the second configuration e.g., a slightly curved configuration (e.g., FIG. 6) (e.g., a curved to between 10 to 45 degrees and/or between 45 to 90 degrees and/or between 90 to 135 degrees) to a second configuration, e.g., round or fully curved configuration (e.g., FIG. 7) (e.g., forming a closed shape and/or forming a closed curve over between 135 to 170 degrees and/or between 170 to 180 degrees). For example, a first switch (e.g., an on-screen button 506 and/or a physical button 606 on face of the device and/or a physical button 706 on a side of the device may switch the device to a flat configuration and/or a second switch (e.g., an on-screen button 502 and/or a physical button 602 on face of the device and/or a physical button 702 on a side of the device may switch the device to a flat configuration.

Alternatively, and/or additionally, the smartphone may include a lock code to change configuration, e.g., a lock code to lock and/or unlock the smartphone configuration. Optionally, the lock code may include a button or a series of buttons 502, 602, 702 to unlock the smartphones configuration. Optionally, the lock code button may be graphical and/or physical. Optionally, the lock code button may be located on a side of the wearable smartphone. Optionally, the lock code button may be located on the screen 504, 604, 704 of the wearable smartphone. Alternatively, and/or additionally, the smartphone may include a configuration transformation button, e.g., change the smartphone configuration reversibly from a first configuration to a second configuration. Optionally, the configuration transformation button may be a button or a series of buttons 506, 606, 706 to unlock the smartphones configuration. Optionally, the configuration transformation button may be graphical and/or physical. Optionally, the configuration transformation button may be located on a side of the wearable smartphone.

Alternatively, and/or additionally, the smartphone may be partially wrapped, e.g., between 0 degrees to 360 degrees to form a circle and/or oval until perfectly flat. Alternatively, and/or additionally, the product may wrap more than 360 degrees. Alternatively, and/or additionally, the device may be curved. Various embodiments may be able to be wrapped until different ranges, e.g., Maximum curvature may be between perfectly flat (0 degrees) to a circle or oval (360 degrees) and/or curved to any subrange between 0 degrees and 360 degrees, e.g., in order to accommodate various sizes and/or fits. Optionally, the curvature may be towards and/or away from the screen. Alternatively, and/or additionally, the smartphone may be wrapped multiple times around, e.g., maximum curvature may be up to 180 degrees

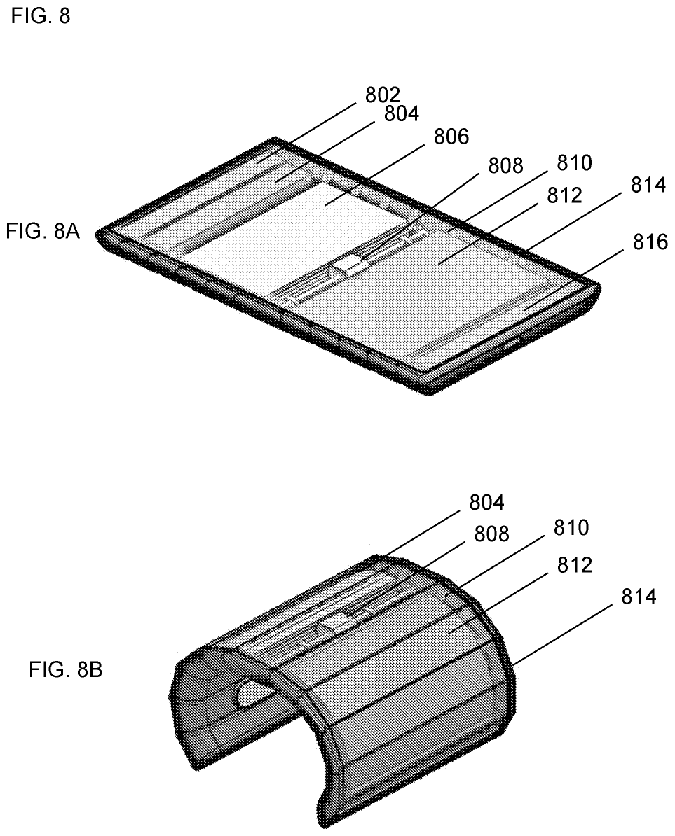

FIGS. 8A-B are schematic diagrams illustrating optional components that the device may possess in accordance with an embodiment of the current invention. For example, the wearable smartphone may include an actuator 808 that may cause the smartphone to change configuration, e.g., a motor and/or a spring. Alternatively, and/or additionally, the smartphone structure may be made of connected ribs 814 and/or scales. Alternatively, and/or additionally, the structure may comprise an elastic and/or semi-elastic material. Alternatively, and/or additionally, the smartphone may include a flexible screen 810. Optionally, the smartphone may include a flexible battery/batteries 812. Optionally, the smartphone may include one or more inflexible batteries. Optionally, the multiple inflexible batteries may be sized to fit in and/or on one or more ribs and/or scales of the smartphone structure. Optionally, the smartphone may include one or more sensors 802, 804, 816, e.g., microphone, speaker, front camera, rear camera, antenna, GPS, sensors, etc. Optionally, the structure may include a processor (CPU) 806.

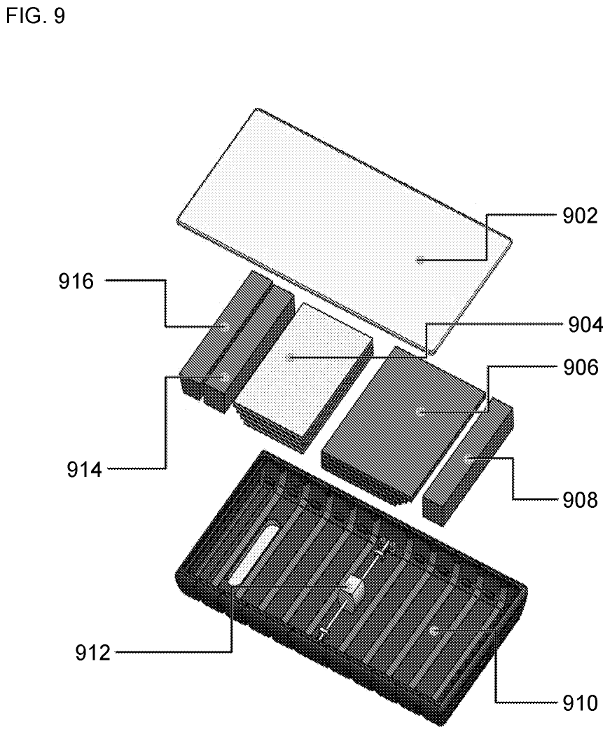

FIG. 9 is a schematic expanded view illustrating a device in accordance with an embodiment of the current invention. According to some embodiments, the illustration shows various components that may be included in the wearable smartphone. Alternatively, and/or additionally, the various components in the smartphone may be flexible. Alternatively, and/or additionally, various components may be slightly flexible and/or inflexible, but they may be on and/or attached to one or more ribs and/or scales thereby they may remain constant in their form and/or the connectors between components may be flexible. Alternatively, and/or additionally, the smartphone may include one or more sensors, e.g., a camera.

For example, the wearable smartphone may include a flexible screen 902, a processor (CPU) 906, one or more sensors 908, 914, 916, e.g., microphone, speaker, front camera, rear camera, antenna, GPS, sensors, etc. Optionally, the smartphone may include a flexible battery/batteries 904. Optionally, the smartphone may include multiple inflexible batteries. Optionally, the multiple inflexible batteries may be sized to fit in and/or on one or more ribs 910 and/or scales of the smartphone structure. Optionally, the smartphone may include an actuator 912 that may cause the smartphone to change configuration

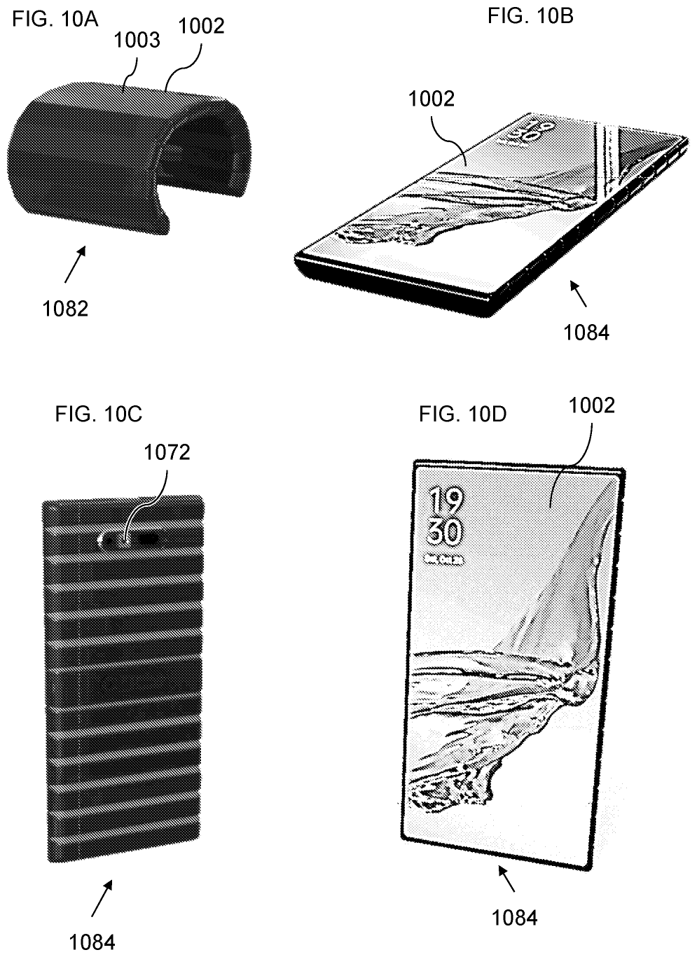

FIGS. 10A-10D are schematic diagrams illustrating various configurations of a device in accordance with an embodiment of the current invention. For example, FIG. 10A illustrates a curved configuration 1082 with a convex multi section screen 1002 facing outward. For example, FIG. 10B illustrates a rear view of a flat configuration 1084 including a rear camera 1072. For example, FIG. 10C illustrates a side view of a flat configuration 1084. For example, FIG. 10B illustrates a front view of a flat configuration 1084. Alternatively, and/or additionally, the case of the smartphone may be of various colors and/or designs. Alternatively, and/or additionally, the smartphone may be stood up on a flat surface when in a curved configuration and/or in a flat configuration. In some embodiments, in the curved configuration 1082, a flat section 1003 may have a larger flat surface than the other sections. Optionally, the flat section may be in the middle of the phone. Alternatively or additionally, the flat section may be closer to one end than the other.

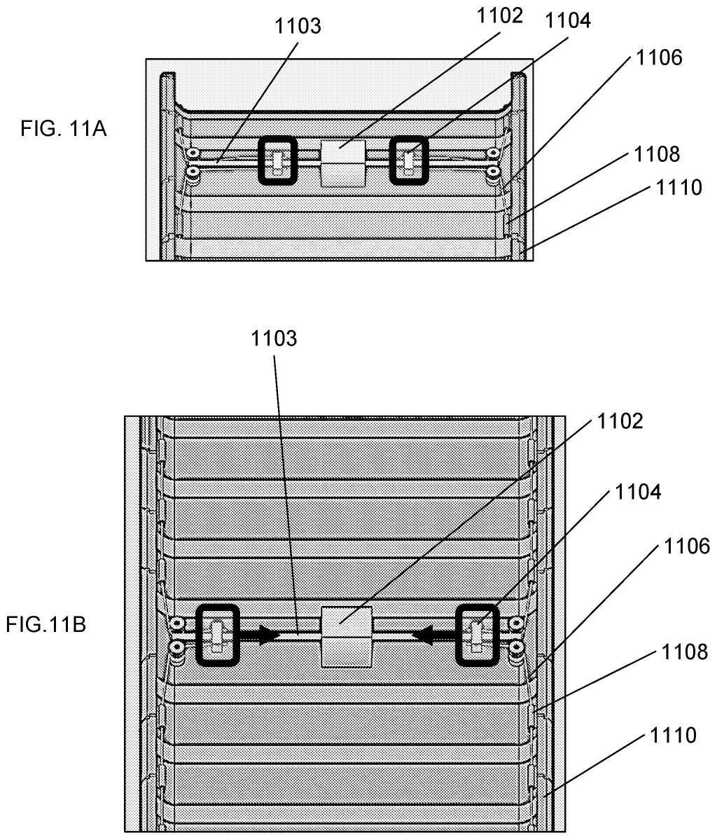

FIGS. 11A-11B are schematic diagrams illustrating a bending apparatus in accordance with an embodiment of the current invention. For example, the smartphone may include strings 1106 of various material that connect to and/or pass through one or more connecting elements 1108 on the tiles 1110 and/or scales of the structure of the smartphone. According to some embodiments, the strings may be attached to a pulling assembly (for example, including a pulley 1104, a threaded axle 1103 and/or a motor 1102). According to some embodiments, motor 1102 may twist axle 1103 and/or push away pulley 1104 and/or release the strings 1106 which may cause the smartphone to change configuration (e.g., flatten out). According to some embodiments, (e.g., as illustrated in FIG. 11B) motor 1102 may twist axle 1103 in a opposite direction and/or pull pulley 1104 and/or pull and/or put tension on the strings 1106 which may cause torsion between the tiles 1110 the smartphone to change configuration (e.g., roll up). For example, the assembly may pull the strings simultaneously to cause torsion between the tiles 1110 thereby causing the tiles to move and/or rotate with respect to one another bending the phone. Additionally, and/or alternatively, the assembly may be locked in a conformation, thereby locking the smartphone in a particular configuration. Alternatively or additionally, a wind-up pulley and/or a linear actuator to pull strings 1106. Alternatively or additionally, a different bending mechanism may be used (for example, magnetic actuators interconnecting the ribs etc.

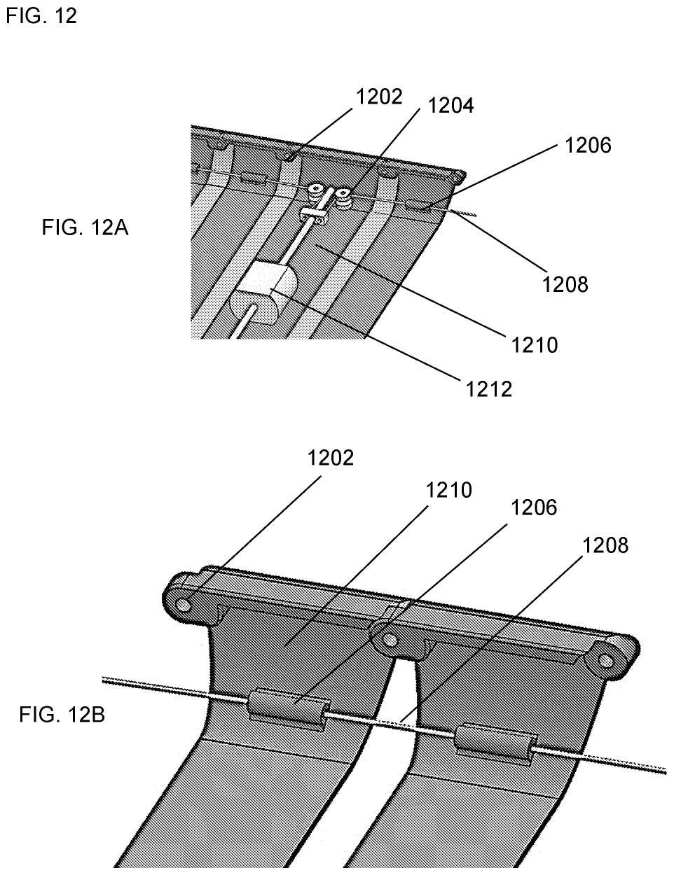

FIGS. 12A-12B are schematic diagrams illustrating a mechanism of a device in accordance with an embodiment of the current invention. For example, the ribs 1210 of the structure of the wearable smartphone may be attached together by one or more hinges 1202. This may allow them to curve together. Alternatively, and/or additionally, each rib 1210 may include one or more strings 1208 threaded through a connecting element 1206 e.g., a supporter, eyelet, loop, etc., that are attached to the rib 1210. Optionally, the one or more strings 1208 may be tightened and/or released by an actuator 1212, which may cause the hinges 1202 to curve and/or the smartphone to change configuration. Optionally, the string 1208 may be directed through a pulley assembly 1204. Optionally the string 1208 may connect the tiles 1210 by means of a connector 1206. For example, the string 1208 may pass through the connector 1206 and/or be attached to the connector 1206.

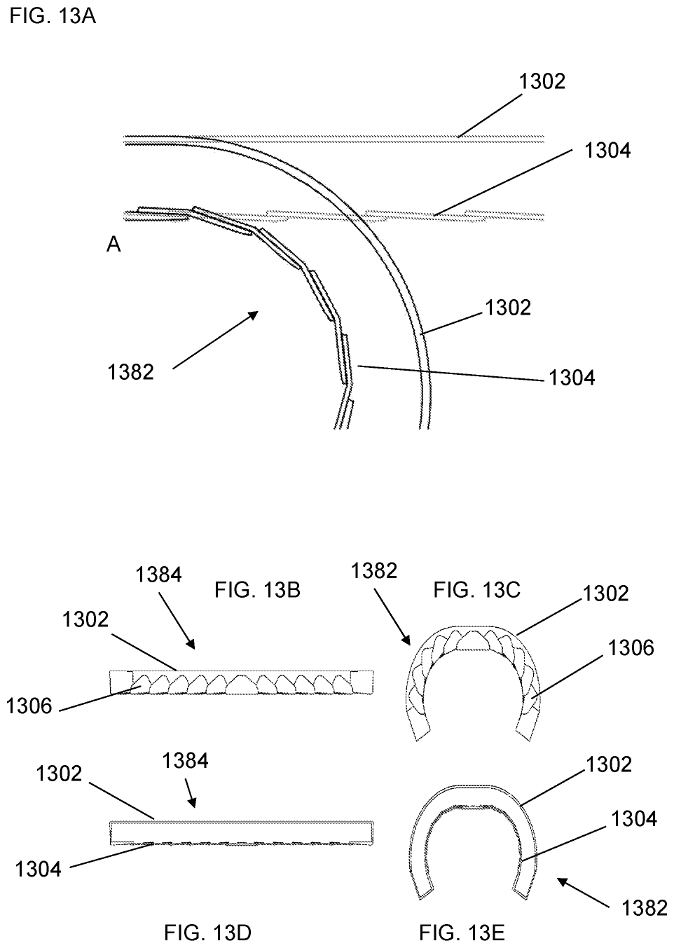

FIGS. 13A-13E are schematic diagrams illustrating a mechanism of a device in accordance with an embodiment of the current invention. For example, a mechanism may transform the wearable smartphone from a flat configuration 1384 (e.g., FIGS. 13A, 13B and 13D) to a curved configuration 1382 (e.g., FIGS. 13A, 13C and 13E). Optionally, the wearable smartphone may include a flexible screen 1302, and a series of tiles e.g., in the form of ribs 1304 and/or scales 1306. Alternatively, and/or additionally, the tiles may lay flat and/or may overlap each other partially and/or completely. Alternatively, and/or additionally, inner tensions may be applied to the tiles, to pull them together. Optionally, the tiles may be pulled together, thereby further overlapping each other. Optionally, inner tension may be released to relax the tiles back to their “normal” positions, and/or to pull the tiles away from each other, thereby overlapping less. For example, a motor releases a string facilitating the ribs straightening the structure. Optionally, the tiles may comprise a material that pulls the smartphone into a flat configuration 1384 and/or there may be an internal pressure that may push the smartphone into a flat configuration 1384. Alternatively or additionally, other mechanisms may transform the phone between the curved configuration 1382 and the flat configuration 1384.

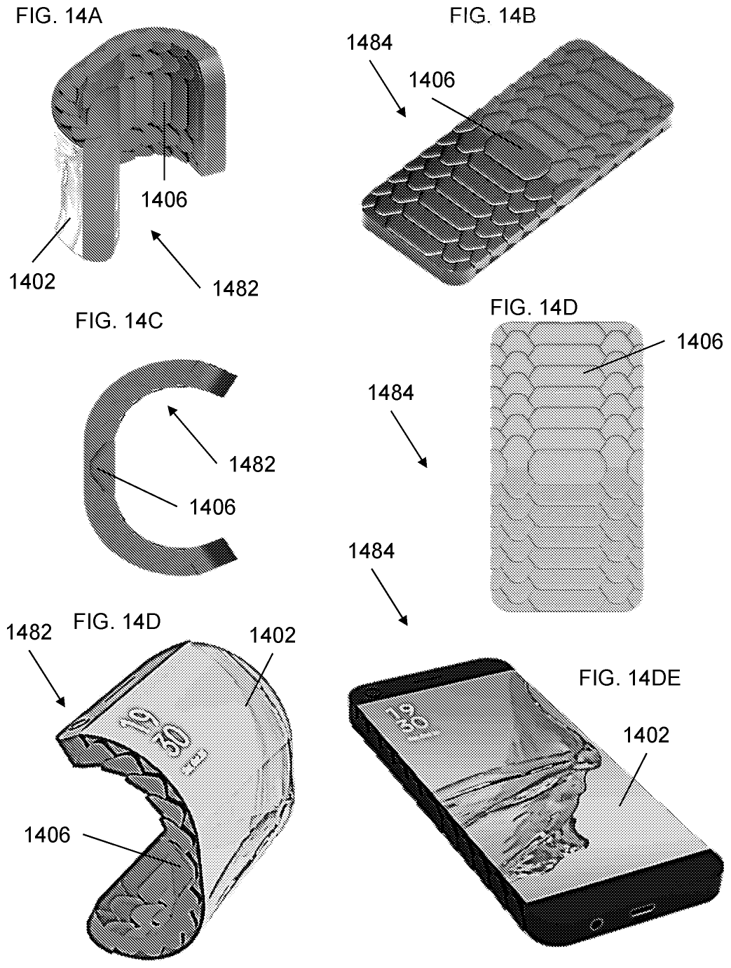

FIGS. 14A-14E are images illustrating a device in accordance with an embodiment of the current invention. For example, a mechanism may transform the wearable smartphone from a flat configuration 1484 (e.g., FIGS. 14B, 14D and 14E) to a curved configuration 1482 (e.g., FIGS. 14A, 14C and 14D). Optionally, the wearable smartphone may include a flexible screen 1402, and a series of tiles e 1406. Alternatively, and/or additionally, the tiles may lay flat and/or may overlap each other partially and/or completely. Alternatively, and/or additionally, inner tensions may be applied to the tiles, to pull them together. Optionally, the tiles may be pulled together, thereby further overlapping each other. Optionally, inner tension may be released to relax the tiles back to their “normal” positions, and/or to pull the tiles away from each other, thereby overlapping less. For example, a motor releases a string facilitating the ribs straightening the structure. Optionally, the tiles may comprise a material that pulls the smartphone into a flat configuration 1484 and/or there may be an internal pressure that may push the smartphone into a flat configuration 1484. Alternatively or additionally, other mechanisms may transform the phone between the curved configuration 1482 and the flat configuration 1484.

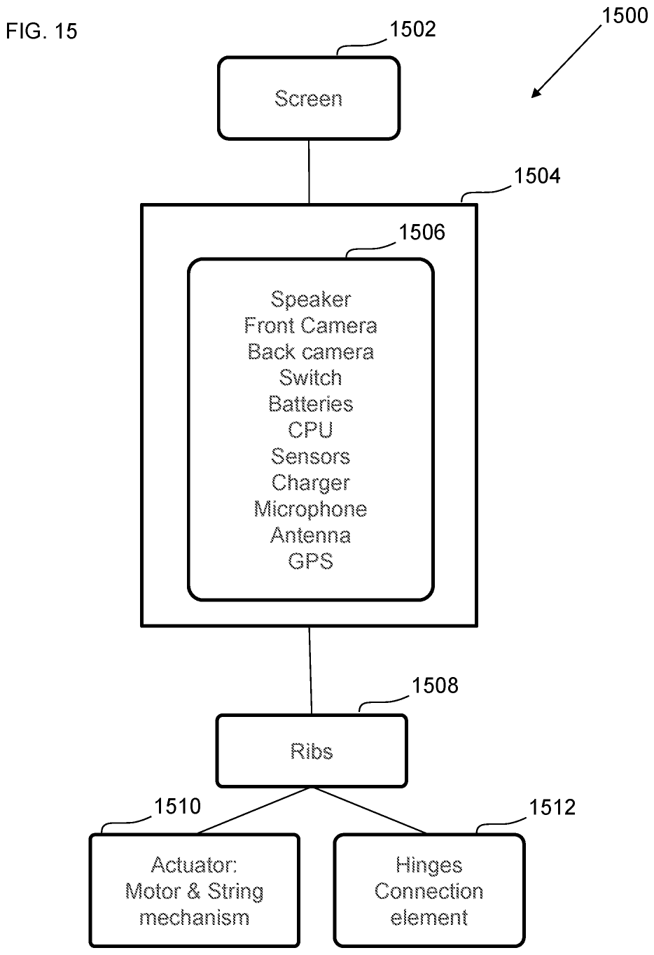

FIG. 15 is a block diagram illustrating a device in accordance with an embodiment of the current invention. For example, the wearable smartphone 1500 may include a screen 1502 with a flexible structure or case 1504, wherein various components 1506 are housed, such as a speaker, microphone, front camera, back camera, switch, batteries, CPU, sensors, charger, antenna, GPS, etc. The structure may include multiple ribs 1508, or scales, wherein the ribs may be connected by one or more hinges and one or more strings 1512 threaded through one or more connection elements. The strings may be attached to an actuator comprising a motor and string mechanism 1510 which may be used to transform the smartphone from one configuration to another. In some embodiments a flexible screen may cover all or some of the flexible structure. In some embodiments, one or more rigid screens may each cover a single element. Optionally, the multiple rigid screens are synchronized to form a composite display.

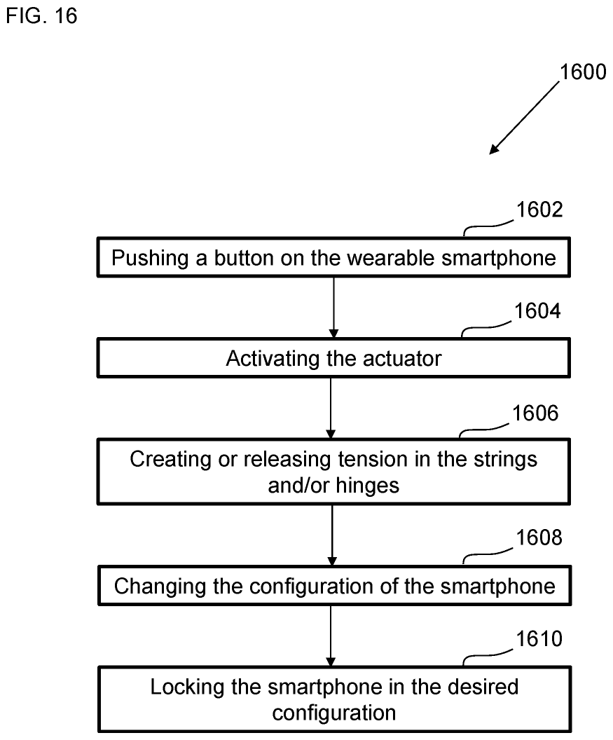

FIG. 16 is a flow diagram illustrating a method for using a device in accordance with an embodiment of the current invention. For example, in the method 1600, the user may push 1602 a button on the wearable smartphone, the button may be graphical and/or physical. This may activate 1604 an actuator connected to one or more strings and/or hinges on one or more ribs of the smartphone structure. This may reversibly create and/or release tension 1606 in the strings and/or hinges of the smartphone structure, which may transform 1608 the configuration of the smartphone. The smartphone may optionally be locked 1610 in the desired configuration.

Advantageously, the wearable smartphone may provide convenience for a user since it may be transformed from configuration to configuration by the push of a button, and locked and/or unlocked in the desired configuration by the push if a button. Additionally, the wearable smartphone may have multiple configurations, being transformed to the desired curvature for maximum convenience. Further, the smartphone may be secured with a security code e.g., around a users' wrist or another object preventing it from being moved or stolen.

### GENERAL

It is expected that during the life of a patent maturing from this application many relevant building technologies, artificial intelligence methodologies, computer user interfaces, image capture devices will be developed and the scope of the terms for design elements, analysis routines, user devices is intended to include all such new technologies a priori.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

As will be appreciated by one skilled in the art, some embodiments of the present invention may be embodied as a system, method or computer program product. Accordingly, some embodiments of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, some embodiments of the present invention may take the form of a computer program product embodied in one or more computer readable medium(s) having computer readable program code embodied thereon. Implementation of the method and/or system of some embodiments of the invention can involve performing and/or completing selected tasks manually, automatically, or a combination thereof. Moreover, according to actual instrumentation and equipment of some embodiments of the method and/or system of the invention, several selected tasks could be implemented by hardware, by software or by firmware and/or by a combination thereof, e.g., using an operating system.

For example, hardware for performing selected tasks according to some embodiments of the invention could be implemented as a chip or a circuit. As software, selected tasks according to some embodiments of the invention could be implemented as a plurality of software instructions being executed by a computer using any suitable operating system. In an exemplary embodiment of the invention, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

Any combination of one or more computer readable medium(s) may be utilized for some embodiments of the invention. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RANI), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, and/or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium and/or data used thereby may be transmitted using any appropriate medium, including but not limited to wireless, wireline, optical fiber cable, RF, etc., or any suitable combination of the foregoing.

Computer program code for carrying out operations for some embodiments of the present invention may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Some embodiments of the present invention may be described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Data and/or program code may be accessed and/or shared over a network, for example the Internet. For example, data may be shared and/or accessed using a social network. A processor may include remote processing capabilities for example available over a network (e.g., the Internet). For example, resources may be accessed via cloud computing. The term “cloud computing” refers to the use of computational resources that are available remotely over a public network, such as the internet, and that may be provided for example at a low cost and/or on an hourly basis. Any virtual or physical computer that is in electronic communication with such a public network could potentially be available as a computational resource. To provide computational resources via the cloud network on a secure basis, computers that access the cloud network may employ standard security encryption protocols such as SSL and PGP, which are well known in the industry.

Some of the methods described herein are generally designed only for use by a computer, and/or may not be feasible or practical for performing purely manually, by a human expert. A human expert who wanted to manually perform similar tasks might be expected to use completely different methods, e.g., making use of expert knowledge and/or the pattern recognition capabilities of the human brain, which would be vastly more efficient than manually going through the steps of the methods described herein.

As used herein the term “about” refers to ±10% The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A wearable smartphone comprising:
a flexible structure comprising a plurality of tiles;
an integrated view screen across a surface including a surface of each of said plurality of tiles;
a switch; and
a bending apparatus configured to reversibly change the smartphone from a flat configuration to a curved configuration in response to activating said switch.

2. The wearable smartphone of claim 1, wherein the view screen includes a flexible portion attached to multiple tiles of the plurality of tiles and bending with the flexible structure.

3. The wearable smartphone of claim 1, wherein each tile of the plurality of tiles is connected to a next tile by at least one hinge.

4. The wearable smartphone of claim 1, wherein the bending apparatus includes at least one string attached to at least one actuator, and wherein the actuator is configured to reversibly put tension on the at least one string, thereby transforming the smartphone from the flat configuration to the curved configuration.

5. The wearable smartphone of claim 4, wherein the string is threaded through at least one connecting element connected to a least one of said plurality of tiles.

6. The wearable smartphone of claim 1, wherein the smartphone is configured transform to an intermediate configuration between the flat configuration and the curved configuration.

7. The wearable smartphone of claim 6, wherein the intermediate configuration is adjustable by a user.

8. The wearable smartphone of claim 1, wherein the wearable smartphone is lockable in a selected configuration.

9. The wearable smartphone of claim 6, wherein the wearable smartphone is lockable in a selected configuration.

10. The wearable smartphone of claim 1, wherein the plurality of tiles overlap at least in part.

11. The wearable smartphone of claim 1, further comprising a flexible battery.

12. The wearable smartphone of claim 1, further comprising at least one inflexible battery attached to at least one tile of said plurality of tiles.

13. The wearable smartphone of claim 1, further comprising one or more components selected from the group consisting of a speaker, microphone, front camera, back camera, switch, batteries, processor, sensors, charger, antenna, Global Positioning System (GPS), magnetometer, proximity sensors, barometer, gyroscope, accelerometer, altimeter, thermometer, projector, Bluetooth, Wi-Fi, multimedia functionality, social media access and wireless communications protocols.

14. The wearable smartphone of claim 1, wherein said switch comprises a button.

15. The wearable smartphone of claim 1, further comprising a button to lock and unlock the smartphone in a desired configuration.

16. The wearable smartphone of claim 14, wherein the button is graphical.

17. The wearable smartphone of claim 15, wherein the button is graphical.

18. The wearable smartphone of claim 14, wherein the button is physical.

19. The wearable smartphone of claim 15, wherein the button is physical.

20. The wearable smartphone of claim 1, wherein the smartphone is operable in the flat configuration, the curved configuration and any intermediate configuration therebetween.

21. The wearable smartphone of claim 1, wherein in the curved configuration the smartphone is curved away from the screen.

22. A method for transforming a wearable smartphone made from a plurality of tiles from a flat configuration to a curved configuration comprising:
triggering a switch on the wearable smartphone;
activating an actuator in response to said triggering;
reversibly creating torsion between at least two of said plurality of tiles; and
transforming the configuration of the smartphone as a result of said reversibly creating torsion.

23. The method of claim 22, wherein said actuator is connected to a string and wherein said activating creates tension in the string which in turn produces said torsion.

24. The method of claim 22, wherein said actuator is connected to a hinge between said at least two of said plurality of tiles and wherein said torsion is on said hinge.

25. The method of claim 22, wherein the transforming is to any intermediate configuration between the flat configuration and the curved configuration.

26. The method of claim 22, wherein the transforming is automatic.

27. The method of claim 22, wherein the transforming is manual.

28. The method of claim 25, wherein a degree of transforming is controlled by a user.

29. The method of claim 22, wherein the flat configuration, the curved configuration and at least one intermediate configuration are defined by a user.

30. The method of claim 22, further comprising reversibly locking the smartphone in a desired configuration.

31. The method of claim 25, further comprising reversibly locking the smartphone in a desired configuration.
